(19) United States
(12) Patent Application Publication
(10) Pub. No.: US 2007/0000655 A1
(43) Pub. Date: Jan. 4, 2007

(54) Heat exchanger for liquid cooling

(75) Inventors: Hiroki Uchida, Kawasaki (JP); Hideshi Tokuhira, Kawasaki (JP); Minoru Ishinabe, Kawasaki (JP); Hiroaki Date, Kawasaki (JP); Jun Taniguchi, Kawasaki (JP)

Correspondence Address: ARENT FOX PLLC, 1050 CONNECTICUT AVENUE, N.W., SUITE 400, WASHINGTON, DC, 20036, US

(73) Assignee: Fujitsu Limited

(21) Appl. No.: 11/255,952

(22) Filed: Oct. 24, 2005

(30) Foreign Application Priority Data
Jul. 1, 2005 (JP) 2005-194110

(51) Int. Cl. H05K 7/20

(52) U.S. Cl. 165/170; 165/80.4; 361/699; 257/714

(57) ABSTRACT

To realize a flat heat exchanger with superior stability of the flow path, a heat exchanger for liquid cooling in which a cooling liquid flows inside the heat exchanger includes a pouch made of a water-resistant sheet having an inflow port and an outflow port for the cooling liquid; a heat exchange plate overlapping with the pouch; a presser plate pressing the pouch against the heat exchange plate; wherein protrusions and depressions delimiting a flow path linking the inflow port and the outflow port are formed on the inner side of at least one of the heat exchange plate and the presser plate.

### BACKGROUND OF THE INVENTION

1. Field of the Invention

The present invention relates to heat exchangers for liquid cooling using forced cooling with a flowing cooling liquid.

2. Description of Related Art

Electronic devices including electronic components that develop too much heat when radiating heat naturally need to be cooled by forced cooling. For example, if personal computers are not cooled so that their CPU is kept within an appropriate temperature region, then they will not operate properly. Ordinarily, forced cooling with cooling air is used in electronic devices.

In recent years, cooling with a cooling liquid, which has a better cooling performance than cooling with cooling air has garnered wide attention as a method for forced cooling in electronic devices. Here, cooling with a cooling liquid refers to a method in which a circulation flow path through a heat receiving portion receiving heat from a heat generating member and a heat radiating portion dissipating heat is provided, and a cooling liquid is circulated forcibly by a pump.

With regard to forced cooling of an electronic device with a cooling liquid, a heat radiator made of a flexible sheet is disclosed in JP 2001-237582A. This heat exchanger is a flat pouch member and has a flow path with a predetermined pattern of a spiral or hairpin-like structure formed by partially adhering opposing inner surfaces to each other. The flow path is planar when it is not filled with cooling medium. When the cooling medium is filled into the flow path, the flexible sheet swells and the flow path expands.

A heat exchanger made of such a flexible sheet deforms easily, so that it is difficult to build dependably into an electronic device. The thermal contact with the electronic device is unreliable and a decrease of the radiation properties due to insufficient contact is likely to occur. If a heat radiator is pressed against the electronic device in order to make the thermal contact more reliable, the pressure with which it is pressed needs to be chosen carefully so as to ensure that the flow path is not destroyed by the pressure.

Also, after the heat radiator has been fabricated, changing the flow path pattern and the dimensions was in practice impossible, and it was not possible to adapt the flow path pattern to changed specifications of the electronic device, such as when using a component with a larger heat generation amount or changing the capability of the circulation pump.

### SUMMARY OF THE INVENTION

It is thus an object of the present invention to provide a flat heat exchanger with superior stability of the flow path.

A heat exchanger achieving the object of the present invention is a heat exchanger for liquid cooling in which a cooling liquid flows inside the heat exchanger, and includes a pouch made of a water-resistant sheet having an inflow port and an outflow port for the cooling liquid; a heat exchange plate overlapping with the pouch; and a presser plate pressing the pouch against the heat exchange plate; wherein protrusions and depressions delimiting a flow path of a predetermined pattern linking the inflow port and the outflow port are formed on the inner side of at least one of the heat exchange plate and the presser plate.

The pouch is sandwiched and pressed together by the heat exchange plate and the presser plate. In the layered structure formed by the heat exchange plate, the pouch and the presser plate, there is a gap between the heat exchange plate and the presser plate whose pattern corresponds to the flow path. The pouch can be deformed within the confines of this gap. When the pouch is filled with cooling liquid, the pouch is deformed along the walls of the gap by the pressure of the cooling liquid, and the space inside the pouch expands. In this state, the gap becomes the flow path of the cooling liquid.

Since the pouch is always pressed from the inside against the heat exchange plate by the pressure of the cooling liquid, the contact state of the heat exchange plate and the pouch is maintained constant, so that a stable cooling performance can be achieved.

In this heat exchanger, it is preferable that the protrusions and depressions delimiting a flow path linking the inflow port and the outflow port are formed on the inner side of the heat exchange plate, and that protrusions and depressions of the same pattern as the protrusions and depressions of the heat exchange plate are formed on the inner side of the presser plate.

By forming protrusions and depressions on both sides of the heat exchange plate and the presser plate, both the front and the rear side of the pouch are flexed, thus forming the flow path, so that the flexure amount of the pouch in forming a flow path of a predetermined cross-sectional area is smaller than when only either the front or the rear side is flexed. That is to say, the requirement of flexibility of the pouch is alleviated, increasing the degree of freedom with which the material of the pouch can be chosen.

It is furthermore preferable that the protrusions and depressions formed on the heat exchange plate or the presser plate are projections with a smooth transition between the level heights of the protrusions and projections.

With a slanted surface structure with a smooth transition between the level heights of the protrusions and projections, air gaps between the pouch on the one hand and the heat exchange plate and the presser plate on the other hand tend to occur less than with a stepped surface structure with sharp transitions, so that the thermal continuity is favorable.

According to the present invention, it is possible to realize a flat heat exchanger with superior stability of the flow path.

### BRIEF DESCRIPTION OF THE DRAWINGS

FIG. 1 shows the configuration of a heat exchanger according to the present invention.

FIG. 2 shows an applied example of a heat radiator according to the present invention.

FIG. 3 shows the cross-sectional configuration of the heat radiator.

FIG. 4 shows a modified example of the structure of the heat radiator.

FIG. 5 shows the cross-sectional structure of a heat absorber according to the present invention.

FIG. 6 shows examples of flow path patterns.

### DETAILED DESCRIPTION OF THE INVENTION

Hereinafter, the present invention will be explained more in detail with reference to embodiments and drawings.

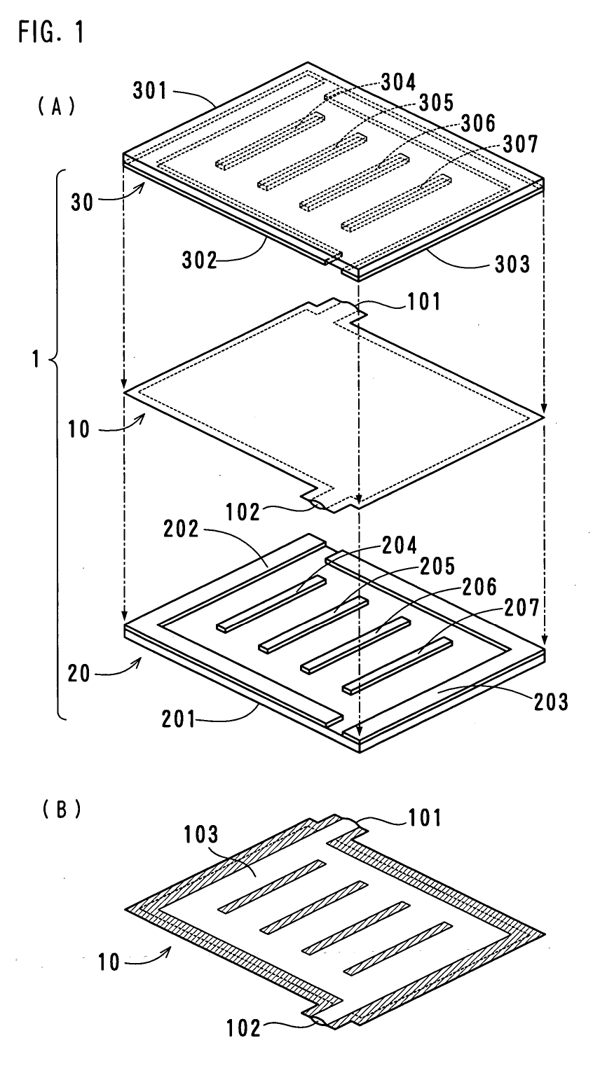

FIG. 1 shows the configuration of a heat exchanger according to an embodiment of the present invention. FIG. 1(A) is an exploded perspective view showing the overall configuration, and FIG. 1(B) is a perspective view of a pouch having a flow path.

A heat exchanger 1 is made of a pouch 10, a heat exchange plate 20 and a presser plate 30, and has a layered structure in which the pouch 10 is sandwiched by the heat exchange plate 20 and the presser plate 30. The heat exchanger 1 is used for forced liquid cooling with a flowing cooling liquid.

The pouch 10 is a flat flexible container having an inflow port 101 and an outflow port 102, and is made of a water-resistant sheet from which the cooling liquid cannot leak. There are not partitions within the pouch 10, and the planar shape of the space containing the cooling liquid substantially conforms to the outer shape of the pouch 10. In the example shown, the planar shape of the pouch 10 is substantially rectangular, and the inflow port 101 and the outflow port 102 are arranged at diagonally opposite positions.

The configuration of the pouch 10 can be adapted as suitable with regard to its planar shape, position of apertures and number of apertures. Regarding the position of the apertures, however, it is preferable that the apertures are arranged at the outer edge of the pouch, in view of making the container thin, the ease with which the apertures can be formed, and the ease of connecting tubes to the apertures. Moreover, by letting the outer edge partially project outward, as shown in the drawing, and forming the apertures at those projecting portions, it is even easier to connect tubes.

The heat exchange plate 20 is made of a material with good heat conductivity that is suitable for heat radiation and/or heat absorption, and has substantially the same size as the pouch 10. The surface on the inner side of the heat exchange plate 20 facing the pouch 10 is provided with protrusions and depressions delimiting a flow path of the cooling liquid.

The heat exchange plate 20 shown in the drawing includes a flat substrate 201 and plate-shaped spacers 202, 203, 204, 205, 206 and 207 that are attached to one side of the flat substrate 201. The spacers all have the same thickness. The spacers 202 and 203 abut against the outer edge portion of the pouch 10. The spacers 204 to 207, which are arranged at a central region of the substrate 201, abut against a central portion of the pouch 10.

The presser plate 30 has the same size as the heat exchange plate 20, and overlaps with the entire heat exchange plate 20. The surface on the inner side of the presser plate 30 facing the pouch 10 is provided with projections and depressions delimiting the flow path of the cooling liquid.

The presser plate 30 shown in the drawing is made of a flat substrate 301 and plate-shaped spacers 302, 303, 304, 305, 306 and 307 that are attached to one side of the flat substrate 301. The spacers all have the same thickness. The spacers 302 and 303 press the outer edge portion of the pouch 10 against the spacers 202 and 203 of the heat exchange plate 20, and prevent a shifting of the position of the pouch 10. The spacers 304 to 307, which are arranged at a central region of the substrate 301, press the central portion of the pouch 10 against the spacers 204 to 207 of the heat exchange plate 20, thus partitioning the internal space of the pouch 10.

The presser plate 30 is fixed to the heat exchange plate 20 with the pouch 10 sandwiched between them. The fixation can be accomplished by one or a plurality of a variety of means, such as using screws, adhesive, rivets or mounting a holding member or the like. It is also possible to provide one or both of the heat exchange plate 20 and the presser plate 30 with interlocking portions such as catch pawls, and to combine the heat exchange plate 20 and the presser plate 30 into one by interlocking them. This approach is in particular preferable if the heat exchange plate 20 or the presser plate 30 is fabricated by molding.

FIG. 1(B) shows the pouch 10 in a state in which it is sandwiched by the heat exchange plate 20 and the presser plate 30. In FIG. 1(B), the region marked by the hatch lines denotes the region that is pressed together by the spacers 202 to 207 (that is, the protrusions on the inner surface of the heat exchange plate 20) and the spacers 302 to 307 (that is, the protrusions on the inner surface of the presser plate 30), whereas the region that is not marked by hatch lines denotes the region constituting the flow path 103. The flow path 103 is connected to the inflow port 101 and the outflow port 102. In the example shown in the drawing, four straight partitions are formed in the pouch 10, and both ends of each of the partitions are away from the outer edge of the pouch 10. The cooling liquid flowing in from the inflow port 101 flows into the branches formed between the partitions and between the partitions and the edge of the pouch, and flows toward the outflow port 102.

In the heat exchanger 1 with the above configuration, the protrusions and depressions at the inner faces of the heat exchange plate 20 and the presser plate 30 are formed by attaching spacers, so that it is possible to change to some extent the pattern and the dimensions of the flow path 103 by increasing or decreasing the number of spacers or exchanging them for other spacers. Consequently, the heat exchanger 1 can be applied to a greater variety of liquid cooling devices than structures having partitions inside the pouch.

However, the approach of forming protrusions and depressions is not limited to attaching spacers. For example, it is also possible to fabricate a heat exchange plate 20 having protrusions and depressions and a presser plate 30 having protrusions and depressions formed by another method, such as molding with a die or cutting the surface of a substrate. In those cases, too, it is possible to change the flow path pattern by adding spacers.

The heat exchanger 1 can be utilized as a heat radiator that receives and dissipates heat from the cooling liquid, or as a heat absorber that receives heat from a heat generating member and transmits it to the cooling liquid.

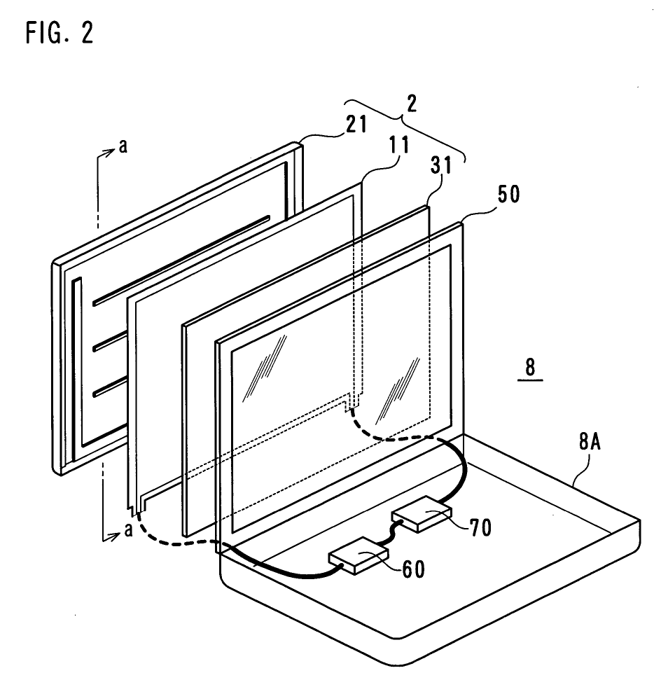

FIG. 2 shows an applied example of a heat radiator according to the present invention.

In FIG. 2, a notebook-type personal computer 8 includes a main unit 8A, a flat panel display 50, such as a liquid crystal display, and a heat radiator 2. Although not shown in the drawing, a variety of electronic components, including a CPU, which is a typical heat source, are built into the main unit 8A, which is also provided with a keyboard and a pointing device. The flat panel display 50 is attached openably and closably to one edge of the main unit 8A as an overlay cover. The heat radiator 2 is disposed such that it covers the rear side of the flat panel display 50 (the side on the rear of the display side), and turns together with the flat panel display 50. The configuration of the heat radiator 2 is as follows.

The heat radiator 2 is configured of a laminate pack 11, a heat radiating plate 21 and a presser plate 31, and has a layered structure, in which the heat radiating plate 21 and the presser plate 31 sandwich the laminate pack 11. The orientation of the heat radiator 2 is such that the presser plate 31 faces the flat panel display 50.

The laminate pack 11 is a flat flexible container having an inflow port and an outflow port. There are no partitions inside the laminate pack 11. An example of the material for the laminate pack 11 is a layered film of several dozen μm thickness with a polyethylene layer as the base. The planar size of the laminate pack 11 is set to a size that is slightly smaller than the outer size of the flat panel display 50 (e.g. 17 inches diagonally), in order to maximize the heat radiation surface. The planar shape of the laminate pack 11 is therefore necessarily substantially rectangular, in correspondence with the flat panel display 50.

The inflow port and the outflow port of the laminate pack 11 are arranged at the lower edge of the laminate pack 11, that is, at positions close to the turn axis of the flat panel display 50. Moreover, predetermined tubing connects the inflow port and the outflow port with a flow path including a heat receiving section 60 and an electric pump 70 inside the main unit 8A of the personal computer 8. Thus, a circulation flow path from the heat receiving section 60 through the laminate pack 11 and the electric pump 70 and back to the heat receiving section 60 is established in the personal computer 8.

The heat radiating plate 21 is an upper cover forming one portion of the casing of the personal computer 8. The inner side of the heat radiating plate 21 facing the laminate pack 11 is provided with protrusions and depressions that delimit the flow path of the cooling liquid. A method for fabricating the heat radiating plate 21 that is suitable for mass production is that of molding it in one piece with the protrusions and depressions using a die. A suitable material for the heat radiating plate 21 is a magnesium alloy.

The presser plate 31 has the function of pressing the laminate pack 11 against the heat radiating plate 21, and setting the thermal resistance between the laminate pack 11 and the flat panel display 50. The presser plate 31 functions for example as a thermal insulation plate. In this case, the heat radiator 2 radiates mainly the heat that was received at the heat receiving section 60. If the cooling capability of the circulation flow path is sufficiently large compared to the amount of heat emitted by the heat source inside the main unit 8A, then it is also possible to devise the presser plate 31 as a heat spreader. In this case, the heat radiator 2 radiates the heat from the heat receiving section 60 as well as the heat from the flat panel display 50.

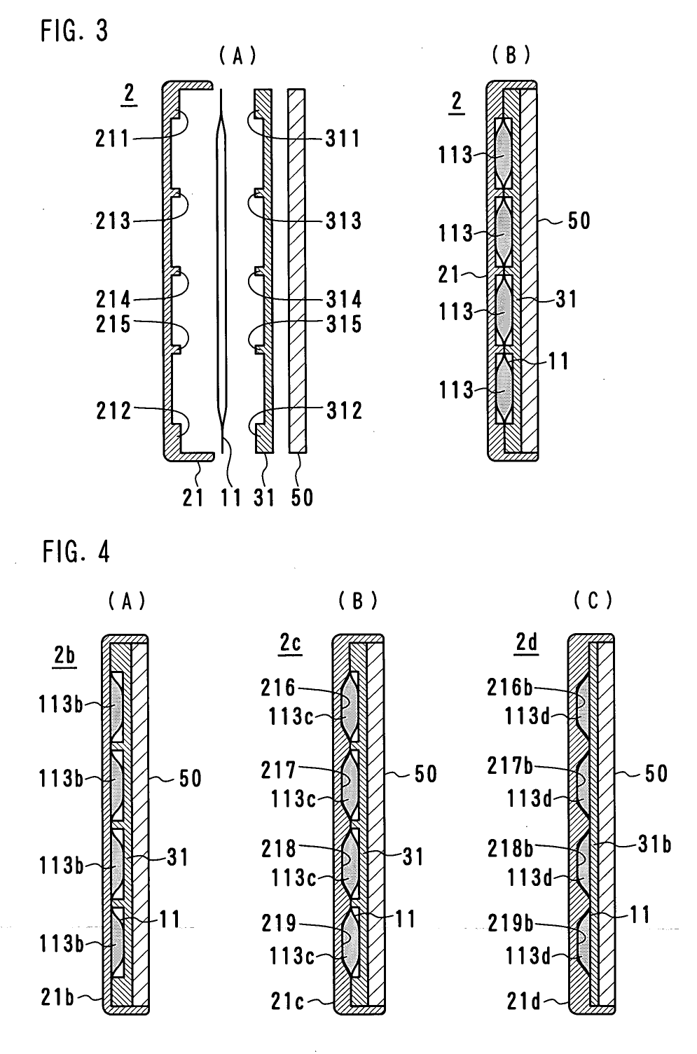

FIG. 3 is a cross-sectional view in arrow direction taken along a-a in FIG. 2, and shows the cross-sectional configuration of the heat radiator. In FIG. 3(A), the heat radiator 2 is shown in a state in which it is taken apart, whereas FIG. 3(B) shows the heat radiator 2 in the state in which it is used.

As shown in FIG. 3(A), the inner side of the heat radiating plate 21 is an uneven surface having protrusions 211, 212, 213, 214 and 215 of about 0.5 mm to 2 mm height. Moreover, also the inner side of the presser plate 31 (the side facing the laminate pack 11) is an uneven surface having protrusions 311, 312, 313, 314 and 315 of about 0.5 mm to 2 mm height. The protrusions 211 to 215 and the protrusions 311 to 315 partially clamp the laminate pack 11, so that the inside of the laminate pack 11 is partitioned as shown in FIG. 3(B). The laminate pack 11 can expand in the thickness direction within the range of the gaps between the heat radiating plate 21 and the presser plate 31. In the usage state in which it is filled with cooling liquid, it is expanded by the pressure of the cooling liquid, and the inner space of the laminate pack 11 becomes the flow path 113.

The planar pattern of the flow path 113 depends on the uneven pattern on the heat radiating plate 21 and the presser plate 31. The flow path can be formed to any suitable pattern, such as a stripe pattern having at least one branch, a spiral pattern, a meandering pattern or a combination of these. It should be noted, however, that the level difference of the protrusions and depressions in the heat radiating plate 21 and the presser plate 31 needs to be selected in view of the flexibility and the elasticity of the laminate pack 11, so that the contact area between the heat radiating plate 21 and the laminate pack 11 does not become too small.

By forming these protrusions and depressions on both the heat radiating plate 21 and the presser plate 31, the flow path 113 is formed by deforming both sides of the laminate pack 11, so that the deformation amount of the one side of the laminate pack 11 when forming the flow path 113 of a predetermined cross section is smaller than in the case that only one side is deformed. That is to say, the need of flexibility and elasticity of the pouch is somewhat alleviated, increasing the number of materials that can be chosen for the laminate pack 11.

FIG. 4 shows modified examples of the structure of the heat radiator. In FIG. 4, structural elements that are the same as in FIG. 3 are denoted by the same reference numerals. In order to avoid duplicate explanations, further explanations regarding these structural elements have been omitted.

The heat radiator 2b in FIG. 4(A) includes a heat radiating plate 21b. The inner side of the heat radiating plate 21b is substantially flat. In the heat radiator 2b, the flow path 113b is delimited by a presser plate 31 having an uneven surface.

In the heat radiator 2b, the face of the laminate pack 11 on the side of the heat radiating plate does not need to be deformed. Consequently, it is possible to make the surface on the side of the heat radiating plate and the surface on the side of the presser plate of sheets of different materials. That is to say, the sheet on the side of the heat radiating plate can be selected regardless of its flexibility and elasticity, and the material can be selected focusing on its thermal conductivity.

The heat radiator 2c in FIG. 4(B) is provided with a heat radiating plate 21c. The inner side of the heat radiating plate 21c has depressions 216, 217, 218 and 219, and there is a smooth transition between the level heights of the depressions and the protrusions. Such an uneven surface is more advantageous with regard to letting the heat radiating plate 21c and the laminate pack 11 contact each other without stress than an uneven surface in which there is a sharp transition between the level heights of the depressions and the protrusions. With this heat radiator 2c, the contact area between the heat radiating plate 21c and the laminate pack 11 can be made large, so that it is easy to establish a good thermal connection between the heat radiating plate 21c and the laminate pack 11.

The heat radiator 2d in FIG. 4(C) is provided with a heat radiating plate 21d and a presser plate 31b. The inner side of the heat radiating plate 21d has depressions 216b, 217b, 218b and 219b, and there is a smooth transition between the level heights of the depressions and the protrusions. On the other hand, the presser plate 31b is a flat plate whose inner side is flat. In the heat radiator 2d, the flow path 113d is delimited by the heat radiating plate 21d, which has an uneven surface.

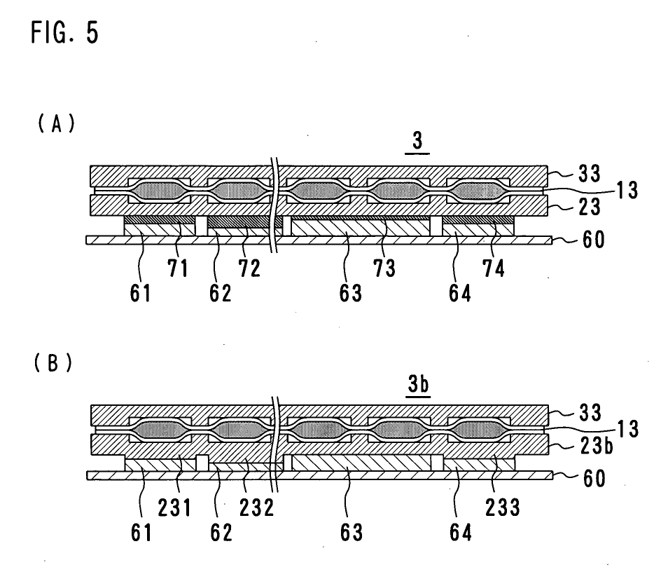

FIG. 5 shows the cross-sectional structure of a heat absorber according to the present invention.

In FIG. 5(A), the heat absorber 3 is made of a laminate pack 13, a heat receiving plate 23 and a presser plate 33, and has a layered structure, in which the heat receiving plate 23 and the presser plate 33 sandwich the laminate pack 13. The laminate pack 13 is a flat flexible container, like the laminate pack 11 of the heat radiator 2, and has an inflow port and an outflow port. The inside of the laminate pack 13 is not partitioned. The surface on the inner side of the heat receiving plate 23 is provided with protrusions and depressions that delimit the flow path of the cooling liquid in the laminate pack 13. Moreover, the inner side of the presser plate 33 is provided with protrusions and depressions of the same pattern as the heat receiving plate 23. That is to say, the basic structure of the heat absorber 3 is the same as that of the heat exchanger 1 in FIG. 1.

The heat absorber 3 is used to cool circuit components 61, 62, 63 and 64 mounted onto a circuit board 60. Therefore, the planar size of the heat absorber 3 is selected such that the entire region where the circuit components 61, 62, 63 and 64 are disposed on the circuit board 60 is overlapped by the heat absorber 3.

When used, the heat absorber 3 overlaps the circuit board 60 such that the heat receiving plate 23 faces the circuit components 61 to 64. In the example shown in the drawing, the outer surface of the heat receiving plate 23 is flat, and the circuit components 61, 62, 63, and 64 do not have the same height, so that thermal sheets 71, 72, 73 ad 74 are arranged between the heat receiving plate 23 and the circuit components 61, 62, 63 and 64. The thermal sheets 71 to 74 are elastic members with high thermal conductivity. By providing the thermal sheets 71 to 74, the gaps between the heat receiving plate 23 and the circuit components 61, 62, 63, and 64 are closed.

In the heat absorber 3b in FIG. 5(B), the heat receiving plate 23 of the heat absorber 3 in FIG. 5(A) is replaced with a heat receiving plate 23b. The inner surface of the heat receiving plate 23b is an uneven surface, just like the inner surface of the heat receiving plate 23. The outer surface of the heat receiving plate 23b is not flat, but is a stepped surface having protrusions 231, 232 and 233 corresponding to the height of the circuit components 61, 62, 63 and 64. With this stepped surface, the circuit components 61, 62, 63 and 64 likewise face the heat receiving plate 23b. In order to improve the thermal conduction, it is preferable that thermal grease is disposed between the heat receiving plate 23b and the circuit components 61, 62, 63 and 64.

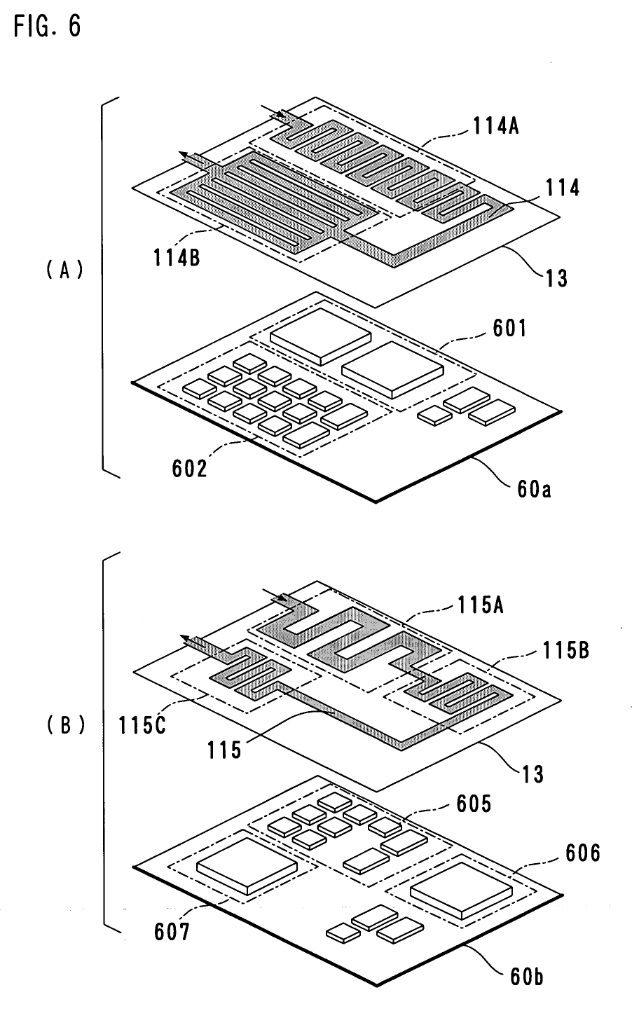

FIG. 6 shows examples of flow path patterns.

In the example in FIG. 6(A), the amount of heat generated by the region 601 of the circuit board 60a is comparatively large, whereas the amount of heat generated by the region 602 is comparatively small. In the flow path 114 of the laminate pack 13, the portion 114A overlapping with the region 601 is devised as a finely meandering pattern, in order to increase the flow speed. On the other hand, the pattern 114B overlapping with the region 602 in the flow path 114 is devised as a striped pattern having a plurality of parallel branch paths, in order to reduce pressure losses.

In the example in FIG. 6(B), the amount of heat generated by the region 605 of the circuit board 60b is comparatively small, whereas the amount of heat generated by the region 606 and the region 607 is comparatively large. In the flow path 115 of the laminate pack 12, the portion 115A overlapping with the region 605 is devised as a meandering pattern with a broad flow path, in order to reduce pressures losses. On the other hand, the portion 115B overlapping with the region 606 and the portion 115C overlapping with the region 607 are devised as narrow meandering patterns, in order to increase the flow speed.

In the foregoing embodiments, there are no partitions inside the laminate packs 11 and 13, so that laminate packs 11 and 13 with common specifications can be used for the cooling of devices to be cooled that necessitate different flow path patterns. The laminate packs 11 and 13 without partitions are cheaper than laminate packs with partitions, so that they are suitable for the cooling of a diverse range of devices. It should be noted however, that it is also possible to provide only the partitions that are common to a plurality of flow path patterns, and to use the protrusions and depressions that are provided in the heat exchange plate 20 or the presser plate 30 for the partitions that are unique for the individual flow path patterns.

Moreover, in the foregoing embodiments, a cooling liquid flows inside the pouch, and the pouch is mechanically protected by the heat exchange plate and the presser plate, so that leaking of the cooling liquid tends not to occur.

In the above-described embodiments, the configuration of the heat exchanger 1, the heat radiator 2 and the heat absorber 3 can be changed as appropriate within the spirit of the present invention. There is no limitation to the material and shape of the structural elements to those noted in the examples. Also, there is no limitation to the cooling of electronic devices, including computers, and it is also possible to apply the present invention to the cooling of other heat generating members.

The present invention can be applied to forced cooling with cooling liquids, and is particularly useful for heat exchange components built into electric devices in which it is important to prevent the leakage of liquids, for example in information processing devices such as personal computers and server computers in particular.

The invention may be embodied in other forms without departing from the spirit or essential characteristics thereof. The embodiments disclosed in this application are to be considered in all respects as illustrative and not limiting. The scope of the invention is indicated by the appended claims rather than by the foregoing description, and all changes which come within the meaning and range of equivalency of the claims are intended to be embraced therein.

What is claimed is:

1. A heat exchanger for liquid cooling in which a cooling liquid flows inside the heat exchanger, comprising:
a pouch made of a water-resistant sheet having an inflow port and an outflow port for the cooling liquid;
a heat exchange plate overlapping with the pouch; and
a presser plate pressing the pouch against the heat exchange plate;
wherein protrusions and depressions delimiting a flow path linking the inflow port and the outflow port are formed on an inner side of at least one of the heat exchange plate and the presser plate.

2. The heat exchanger according to claim 1,
wherein the protrusions and depressions delimiting the flow path linking the inflow port and the outflow port are formed on the inner side of the heat exchange plate; and
wherein protrusions and depressions of the same pattern as the protrusions and depressions of the heat exchange plate are formed on the inner side of the presser plate.

3. The heat exchanger according to claim 1,
wherein the protrusions and depressions formed on the heat exchange plate or the presser plate are projections with a smooth transition between the level heights of the protrusions and projections.

4. A heat radiator for liquid cooling in which a cooling liquid flows inside the heat radiator, comprising:
a laminate pack having an inflow port and an outflow port for the cooling liquid;
a heat radiating plate overlapping with the laminate pack; and
a presser plate pressing the laminate pack against the heat radiating plate;
wherein protrusions and depressions delimiting a flow path linking the inflow port and the outflow port are formed on an inner side of at least one of the heat radiating plate and the presser plate.

5. A heat absorber for liquid cooling in which a cooling liquid flows inside the heat absorber, comprising:
a laminate pack having an inflow port and an outflow port for the cooling liquid;
a heat receiving plate overlapping with the laminate pack; and
a presser plate pressing the laminate pack against the heat receiving plate;
wherein protrusions and depressions delimiting a flow path linking the inflow port and the outflow port are formed on an inner side of at least one of the heat receiving plate and the presser plate.
